(19) United States
(12) Patent Application Publication
(10) Pub. No.: US 2006/0280023 A1
(43) Pub. Date: Dec. 14, 2006

(54) Semiconductor memory device using a ferroelectric capacitor

(76) Inventors: Katsuhiko Hoya, Yokohama-shi (JP); Tohru Ozaki, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(21) Appl. No.: 11/440,110

(22) Filed: May 25, 2006

(30) Foreign Application Priority Data
May 26, 2005 (JP) 2005-153945

(51) Int. Cl. G11C 8/00

(52) U.S. Cl. 365/230.03

(57) ABSTRACT

A semiconductor memory device includes a row of memory cells connected in series, each of the memory cells including a ferroelectric capacitor and a cell transistor having a gate terminal and source/drain terminals, the source/drain terminals being connected in parallel with two electrodes of the ferroelectric capacitor, a word line connected to the gate terminal, memory cell blocks each including the row of memory cells and a block select transistor, a drain terminal of the block select transistor being connected to one end of the row of memory cells, a plate line connected to another end thereof, a bit line connected to a source terminal of the block select transistor, and a block select line connected to a gate terminal of the block select transistor, wherein a contact is provided under the plate line to connect the source terminal of the block select transistor and the bit line.

### CROSS-REFERENCE TO RELATED APPLICATIONS

This application is based upon and claims the benefit of priority from prior Japanese Patent Application No. 2005-153945, May 26, 2005, the entire contents of which are incorporated herein by reference.

### BACKGROUND OF THE INVENTION

1. Field of the Invention

The present invention relates to a nonvolatile semiconductor memory device. More specifically, the invention relates to a ferroelectric random access memory (FeRAM) of a series-connected TC unit type using a ferroelectric capacitor.

2. Description of the Related Art

A ferroelectric random access memory (FeRAM) using a ferroelectric capacitor has recently been noted as a nonvolatile semiconductor memory device. The FeRAM stores binary data nonvolatilely according to the intensity of two different polarizations (amount of remanent polarization) of a ferroelectric, using the fact that spontaneous polarization, which is one characteristic of the ferroelectric, exhibits hysteresis.

The memory cells (unit cells) of a prior art ferroelectric random access memory (FeRAM) generally adopt architecture similar to that of a dynamic random access memory (DRAM). More specifically, the unit cells of the FeRAM are each configured by replacing a paraelectric capacitor of the DRAM with a ferroelectric capacitor and then connecting the ferroelectric capacitor to a cell transistor in series.

Unlike the DRAM, the FeRAM holds data according to the amount of remanent polarization. In order to read signal charges on bit lines, a potential difference needs to occur between the electrodes of the ferroelectric capacitor and in general plate lines are driven. In other words, the FeRAM requires a plate line driving circuit, and the plate line driving circuit has to be provided for each plate line. Thus, the area of the plate line driving circuit occupied in a chip increases, as does the area of the chip.

In contrast, a ferroelectric random access memory (FeRAM) capable of preventing a plate line driving circuit from increasing in area is proposed in, for example, D. Takashima et al., “High-Density Chain Ferroelectric Random Memory (CFeRAM)” in proc. VLSI Symp. June 1997, pp. 83-84. This FeRAM is of a series-connected TC unit type and includes unit cells. Each of the unit cells is configured by a ferroelectric capacitor (C) and a cell transistor (T). The electrodes of both ends of the ferroelectric capacitor (C) are connected to the source and drain of the cell transistor (T). The unit cells are connected in series to form a memory cell block. In this FeRAM, a plate line driving circuit can be shared among the unit cells, thereby increasing a cell array in packing density.

In the prior art FeRAM of a series-connected TC unit type, four block select lines (GC wires) are provided at one end of a memory cell block and two plate lines are provided at the other end thereof. Word lines (GC wires) are linearly formed in the memory cell block, while block select lines are formed nonlinearly therein. In other words, the block select lines have to be curved because of constraints on the area of a diffusion layer and that of a block select line in order to decrease a bit line capacity.

The prior art FeRAM has a layout that depends on design rules between GC wires. In other words, the design rules restrict the reduction of the layout area of block select lines. It causes a problem that the memory cell array cannot be decreased in layout area.

### BRIEF SUMMARY OF THE INVENTION

According to a first aspect of the present invention, there is provided a semiconductor memory device comprising: a row of memory cells connected in series, each of the memory cells including a ferroelectric capacitor and a cell transistor which has a gate terminal and source/drain terminals, the source/drain terminals being connected in parallel with two electrodes of the ferroelectric capacitor; a word line connected to the gate terminal; memory cell blocks each including the row of memory cells and a block select transistor, a drain terminal of the block select transistor being connected to one end of the row of memory cells; a plate line connected to another end of the row of memory cells; a bit line connected to a source terminal of the block select transistor; and a block select line connected to a gate terminal of the block select transistor, wherein a contact is provided under the plate line to connect the source terminal of the block select transistor and the bit line.

According to a second aspect of the present invention, there is provided a semiconductor memory device comprising: a row of memory cells connected in series, each of the memory cells including a ferroelectric capacitor and a cell transistor which has a gate terminal and source/drain terminals, the source/drain terminals being connected in parallel with two electrodes of the ferroelectric capacitor; a word line connected to the gate terminal; memory cell blocks each including the row of memory cells and a block select transistor, a drain terminal of the block select transistor being connected to one end of the row of memory cells; a plate line connected to another end of the row of memory cells; a complementary pair of bit lines each connected to a source terminal of the block select transistor; a first block select line connected to a gate terminal of the block select transistor which is connected to one of the complementary pair of bit lines; and a second block select line connected to a gate terminal of the block select transistor which is connected to other of the complementary pair of bit lines, wherein the memory cell block are provided between the first block select line and the second block select line.

According to a third aspect of the present invention, there is provided a semiconductor memory device comprising: a row of memory cells connected in series, each of the memory cells including a ferroelectric capacitor and a cell transistor which has a gate terminal and source/drain terminals, the source/drain terminals being connected in parallel with two electrodes of the ferroelectric capacitor; a word line connected to the gate terminal; memory cell blocks each including the row of memory cells and a block select transistor, a drain terminal of the block select transistor being connected to one end of the row of memory cells; a plate line connected to another end of the row of memory cells; a bit line connected to a source terminal of the block select transistor; and a block select line connected to a gate terminal of the block select transistor, wherein the memory cell blocks each include x (x is a positive integer) memory cells, and a word line connected to a gate terminal of a y-th (y is a positive integer) memory cell from a block select transistor in a first memory cell block connected to one of complementary pair of bit lines which compose the bit line is connected to a gate terminal of an (x-y+1)-th memory cell from a block select transistor in a second memory cell block connected to other of the complementary pair of bit lines.

### BRIEF DESCRIPTION OF THE SEVERAL VIEWS OF THE DRAWING

FIG. 1 is a circuit diagram showing a memory cell array of a ferroelectric random access memory of a series-connected TC unit type according to a first embodiment of the present invention;

FIG. 2A is a plan view showing an example of the layout of the memory cell array shown in FIG. 1;

FIG. 2B is a sectional view taken along line IIB-IIB of FIG. 2A;

FIG. 2C is a sectional view taken along line IIC-IIC of FIG. 2A;

FIG. 3A is a block diagram showing an array edge of the memory cell array shown in FIG. 1;

FIG. 3B is a plan view showing an example of the layout of the array edge shown in FIG. 3A;

FIG. 4A is a circuit diagram of the memory cell array shown in FIG. 1, illustrating a data read operation;

FIG. 4B is a chart of signal waveforms of the data read operation;

FIG. 5 is a circuit diagram showing a memory cell array of a ferroelectric random access memory of a series-connected TC unit type according to a second embodiment of the present invention;

FIG. 6A is a circuit diagram showing an example of a ferroelectric random access memory of a series-connected TC unit type according to a third embodiment of the present invention;

FIG. 6B is a chart of signal waveforms of the ferroelectric random access memory shown in FIG. 6A;

FIGS. 7A to 7C are diagrams showing another example of the ferroelectric random access memory shown in FIGS. 6A and 6B;

FIGS. 8A to 8C are diagrams showing still another example of the ferroelectric random access memory shown in FIGS. 6A and 6B;

FIGS. 9A to 9C are diagrams showing yet another example of the ferroelectric random access memory shown in FIGS. 6A and 6B; and

FIGS. 10A to 10C are diagrams showing another example of the ferroelectric random access memory shown in FIGS. 6A and 6B.

### DETAILED DESCRIPTION OF THE INVENTION

Embodiments of the present invention will be described with reference to the accompanying drawings.

### First Embodiment

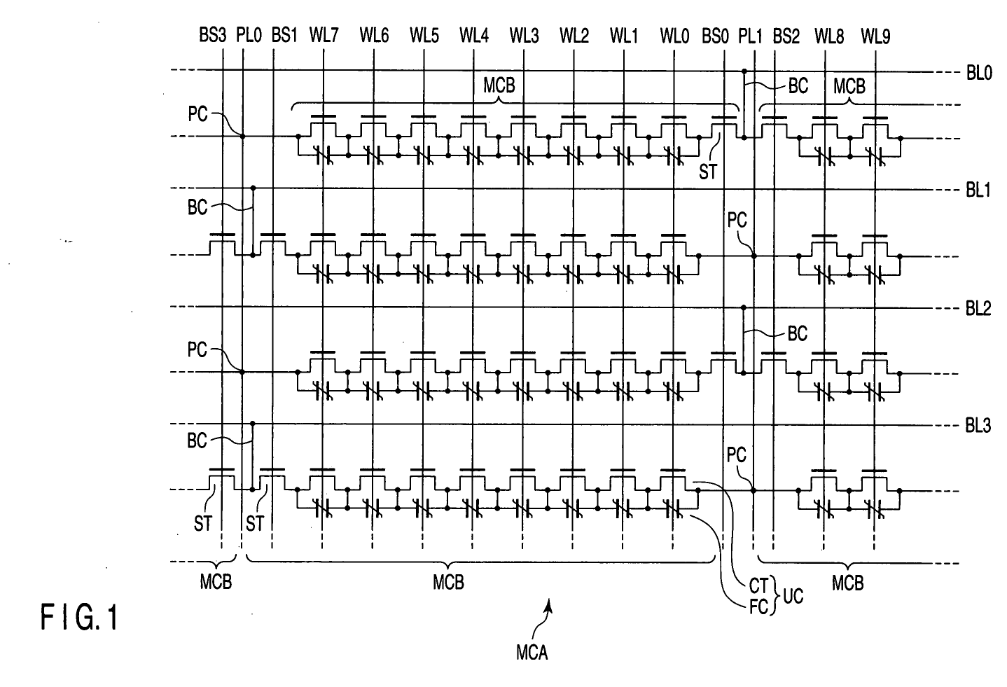

FIG. 1 shows a basic arrangement of a ferroelectric random access memory (FeRAM) (semiconductor memory device) of a series-connected TC unit type according to a first embodiment of the present invention. In the first embodiment, the FeRAM comprises a memory cell array (chain cell block) including memory cell blocks each having eight unit cells (memory cells).

Referring to FIG. 1, a memory cell array MCA comprises a plurality of memory cell blocks MCB. Each of the memory cell blocks MCB includes eight unit cells UC and one block select transistor ST. One end of each cell block MCB is connected to a corresponding bit line BL (BL0, BL1, . . . ) via a contact layer BC, while the other end thereof is connected to a corresponding plate line PL (PL0, PL1) via a contact layer PC.

The unit cells UC each include a ferroelectric capacitor FC and a cell transistor CT. Two terminals (electrodes) of the ferroelectric capacitor FC and source and drain terminals (diffusion layers) of the cell transistor CT are connected in parallel. These eight unit cells UC are connected in series to form a row of cells. The block select transistor ST is connected in series to one end of the row of cells to form the memory cell block MCB described above.

The gate terminal of the cell transistor CT in each unit cell UC is connected to a corresponding word line WL (WL0, WL1, . . . ) that is formed linearly. On the other hand, the gate terminal of the block select transistor ST is connected to a corresponding block select line BS (BS0, BS1, . . . ) that is formed linearly. The block select line BS is supplied with a block select signal SBS. The source terminal of the block select transistor ST is connected to a corresponding bit line BL and the drain terminal thereof is connected to a unit cell UC at one end of the row of cells.

In the first embodiment, two block select lines BS and one plate line PL are linearly arranged between memory cell blocks MCB that are adjacent to each other in the lateral direction of FIG. 1 (bit line direction). In other words, for example, block select lines BS0 and BS2 are provided on one side of each of memory cell blocks MCB that are adjacent to each other in the vertical direction of FIG. 1 (word line direction). A plate line PL1 is provided between these block select lines BS0 and BS2. Further, for example, block select lines BS1 and BS3 are provided on the other side of each of the memory cell blocks MCB. A plate line PL0 is provided between these block select lines BS1 and BS3.

The block select transistors BS2 and BS3 are each connected to the other of the memory cell blocks MCB that are adjacent to each other in the bit line direction, as are the plate lines PL0 and PL1.

In the first embodiment, the block select lines BS0 and BS1 are arranged between the plate lines PL0 and PL1. The memory cell blocks MCB connected to the block select lines BS0 and BS1 are arranged between the block select lines BS0 and BS1. One end of each of memory cell blocks MCB (which are connected to one of paired complementary bit lines), which has a block select transistor ST whose gate terminal is connected to the block select line BS0, is connected to the plate line PL0, and the other end thereof is connected to the bit line BL0 or BL2. Similarly, one end of each of memory cell blocks MCB (which are connected to the other of paired complementary bit lines), which has a block select transistor ST whose gate terminal is connected to the block select line BS1, is connected to the plate line PL1, and the other end thereof is connected to the bit line BL1 or BL3.

The bit lines BL include a plurality of pairs of bit lines (in the first embodiment, two pairs of bit lines BL and /BL: “/” represents “low active”). In other words, a memory cell block MCB having a block select transistor ST on the right side of the row of cells is connected to one of paired complementary bit lines (e.g., BL0 and BL2). In contrast, a memory cell block MCB having a block select transistor ST on the left side of the row of cells is connected to the other of the paired complementary bit lines (e.g., BL1 and BL3).

The word lines WL0, WL1, . . . are connected to their corresponding unit cells UC of the memory cell blocks MCB, which are connected to the bit lines BL0 and BL2, in sequence from the block select transistors ST. On the other hand, the word lines WL0, WL1, are connected to their corresponding unit cells UC of the memory cell blocks MCB, which are connected to the bit lines BL1 and BL3, in sequence from the plate line PL1. In other words, the word line WL1 connected to the gate terminals of the second (y-th) unit cells UC from the block select transistors ST in the memory cell blocks MCB connected to the bit lines BL0 and BL2, is connected to the gate terminals of the seventh ((x-y+1)-th) unit cells UC from the block select transistors ST in the memory cell blocks MCB connected to the bit lines BL1 and BL3.

As described above, the block select lines BS0 and BS2 and plate line PL1 are connected to one end of the memory cell block MCB, while the block select lines BS1 and BS3 and plate line PL0 are connected to the other end thereof. The plate line PL0 can be arranged between the block select lines BS1 and BS3, and the plate line PL1 can be arranged between the block select lines BS0 and BS2. Thus, the contact layer BC that connects the block select transistor ST to which the block select line BS0 is connected and the bit lines BL0 and BL2 can be provided under the plate line PL1. Similarly, the contact layer BC that connects the block select transistor ST to which the block select line BS1 is connected and the bit lines BL1 and BL3 can be provided under the plate line PL0.

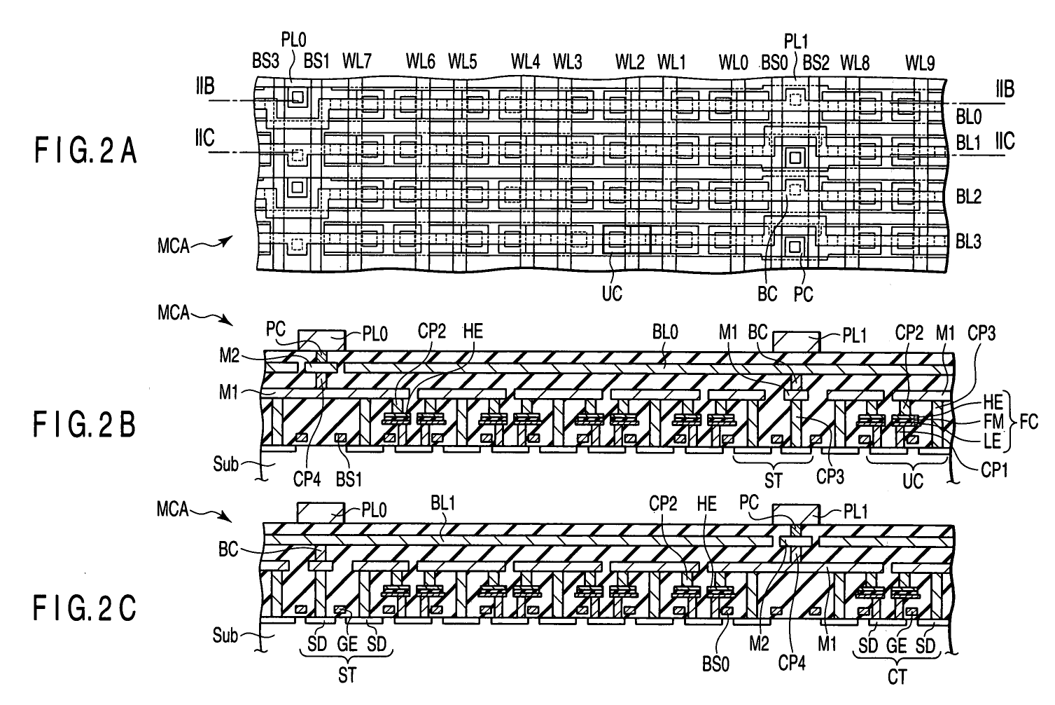

FIG. 2A is a plan view showing an example of the layout of the FeRAM described above, FIG. 2B is a sectional view taken along line IIB-IIB of FIG. 2A, and FIG. 2C is a sectional view taken along line IIC-IIC of FIG. 2A.

Referring to FIGS. 2A to 2C, the cell transistor CT of each unit cell UC includes a gate electrode (word line) GE and source/drain diffusion layers SD and SD. The gate electrode GE is provided on the top surface of a substrate Sub with a gate insulation film (not shown) therebetween. The source/drain diffusion layers SD and SD are provided in the surface area of the substrate Sub. The ferroelectric capacitor FC of each unit cell UC is formed of a lower electrode LE, a ferroelectric film FM and a higher electrode HE. The ferroelectric film FM is interposed between the lower and higher electrodes LE and HE. The lower electrode LE is connected to one (drain terminal) of the source/drain diffusion layers SD and SD via a contact layer CP1. The higher electrode HE is connected to the other (source terminal) of the source/drain diffusion layers SD and SD via a contact layer CP2, a contact wire (M1 layer) M1 and a contact layer CP3.

In the first embodiment, adjacent cell transistors CT employ the same source/drain diffusion layer SD. The unit cells UC of each memory cell block MCB are connected like a chain.

The higher electrode HE of the ferroelectric capacitor FC of the unit cell UC at one end of a row of unit cells UC is connected to the plate line (M3 layer) PL via the contact layer CP2, contact wire M1, contact layer CP4, contact wire (M2 layer) M2 and contact layer PC. More specifically, the unit cell UC at one end of the memory cell block MCB shown in FIG. 2B is connected to the plate line PL0. Similarly, the unit cell UC at the other end of the memory cell block MCB shown in FIG. 2C is connected to the plate line PL1.

The block select transistor ST that is provided at one end of each memory cell block MCB includes a gate electrode (block select line) GE and source/drain diffusion layers SD and SD. The gate electrode GE is provided on the top surface of the substrate Sub with a gate insulation film (not shown) therebetween. The source/drain diffusion layers SD and SD are provided in the surface area of the substrate Sub.

In the first embodiment, one (source terminal) of the source/drain diffusion layers SD and SD of the block select transistor ST is also employed as one (source terminal) of the source/drain diffusion layers SD and SD of the cell transistor CT of the unit cell UC at one end of each memory cell block MCB.

The other (drain terminal) of the source/drain diffusion layers SD and SD is connected to the bit line (M2 layer) BL via the contact layer BC, contact wire M1 and contact layer CP3 under the plate line (M3 layer) PL. More specifically, the block select transistor ST of the memory cell block MCB shown in FIG. 2B is connected to the bit line BL0. Similarly, the block select transistor ST of the memory cell block MCB shown in FIG. 2C is connected to the bit line BL1.

In the first embodiment, a contact wire M2 is formed by the same M2 layer as the bit lines BL. The bit lines BL are therefore arranged to make a detour to avoid the contact wire M2.

As is apparent from FIGS. 2A to 2C, the memory cell block MCB connected to the bit line BL0 and the memory cell block MCB connected to the bit line BL1 each have an almost symmetrical section. In the memory cell blocks MCB in the word line (WL) direction, the contact layers PC for connecting the plate line PL and the memory cell blocks MCB and the contact layers BC for connecting the bit lines BL and the memory cell blocks MCB are arranged alternately. If, therefore, the second unit cell UC from the block select transistor ST is selected in the memory cell block MCB connected to the bit line BL0, the seventh unit cell UC from the block select transistor ST is selected in the memory cell block MCB connected to the bit line BL1.

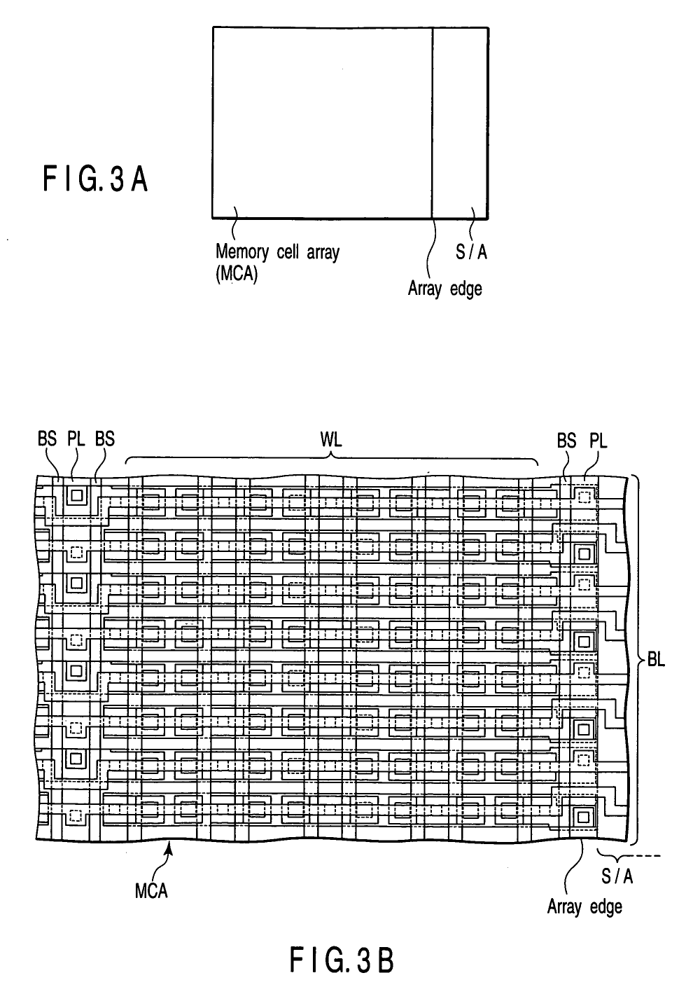

FIG. 3A is a block diagram showing an array edge of the memory cell array of the FeRAM described above. FIG. 3B is a plan view of the actual layout of the array edge shown in FIG. 3A. In the first embodiment, the array edge of a memory cell array MCA connected to a sense amplifier (S/A) need not be laid out specially. It is thus possible to prevent an increase in area due to the array edge.

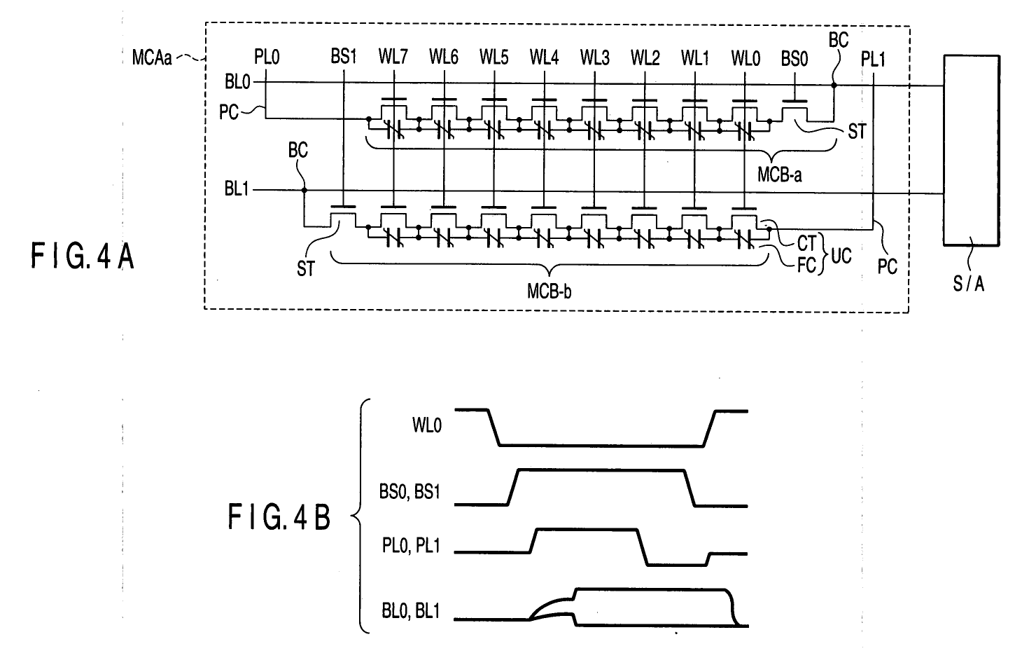

FIGS. 4A and 4B illustrate a method of reading data from the FeRAM described above. FIG. 4A is a circuit diagram of the memory cell array MCA in which memory cell blocks MCB-a and MCB-b are connected to their respective bit lines BL0 and BL1 that are complementary to each other. FIG. 4B is a chart of signal waveforms of the data read operation.

In a 2T/2C system that stores complementary data items using two unit cells UC (two cell transistors CT and two ferroelectric capacitors FC) and determines one-bit data by a comparison between the data items, the potentials of all the word lines WL0 to WL7 are maintained at VPP (high potential) and those of the block select lines BS0 and BS1, bit lines BL0 and BL1 and plate lines PL0 and PL1 are maintained at VSS (low potential) in standby mode. Since the potentials of both ends of each of the ferroelectric capacitors FC are short-circuited by VSS, data can be held with stability.

In active mode, when data is read out of the unit cells connected to the bit lines BL0 and BL1 in accordance with the selection of the word line WL0, the potentials of the bit lines BL0 and BL1 are set in a floating state first. Then, the potential of the word line WL0 decreases to VSS, the potentials of the block select lines BS0 and BS1 increase to VPP, and the plate lines PL0 and PL1 (VSS) are driven by potential VINT. Accordingly, cell data is read onto the bit line BL0 and data complementary to the cell data is read onto the bit line BL1. While the potentials of the plate lines PL0 and PL1 are maintained at VINT after the potentials of both the bit lines BL0 and BL1 are compared and amplified by the sense amplifier S/A, a potential difference occurs only between the bit line on which data “0” is read and the plate line, and the data “0” is rewritten. When the potentials of the plate lines PL0 and PL1 decrease to VSS, a potential difference occurs only between the bit line on which data “1” is read and the plate line, and the data “1” is rewritten. After that, the potentials of the block select lines BS0 and BS1 decrease to VSS, the word line WL2 is driven by potential VPP, and the potentials of the plate lines PL0 and PL1 decrease. The FeRAM returns to the above standby mode.

According to the layout described above, the block select lines can be formed linearly like the word lines. In other words, the arrangement of the block select lines does not depend upon design rules between the block select lines (GC wires). The layout area for the block select lines can thus be reduced; thus, the layout area for the memory cell array can be reduced more than conventional.

In the first embodiment, the area for the source/drain diffusion layer (source terminal) on which a contact layer for connecting the bit lines and the block select transistor is provided, is based on design rules.

### Second Embodiment

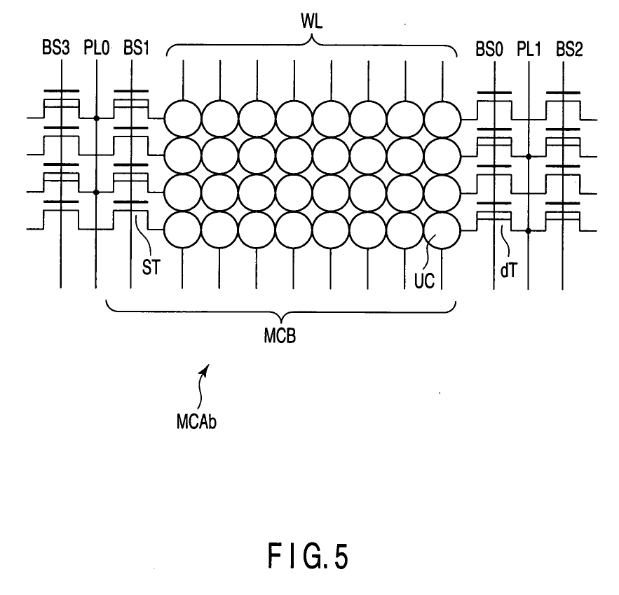

FIG. 5 shows a basic arrangement of a ferroelectric random access memory (FeRAM) of a series-connected TC unit type (semiconductor memory device) according to a second embodiment of the present invention. In the second embodiment, a memory cell block MCB and a plate line PL are connected by a depletion type transistor. In FIG. 5, unit cells UC are represented by circles “◯”, and a contact layer BC for connecting bit lines BL and a memory cell block MCB is omitted for the sake of convenience.

For example, a depletion type transistor dT can be added to the memory cell array MCA according to the first embodiment. In a memory cell array MCAb according to a second embodiment, a block select transistor ST is connected to one end of the memory cell block MCB. In contrast, the other end of the memory cell block MCB is connected to either a plate line PL0 or a plate line PL1 via the transistor dT.

The memory cell array MCAb of the second embodiment, which is formed by adding a depletion type transistor dT to the memory cell array MCA according to the first embodiment, can-produce almost the same advantage as that of the first embodiment. In other words, the layout area for the memory cell array can be reduced more than conventional.

### Third Embodiment

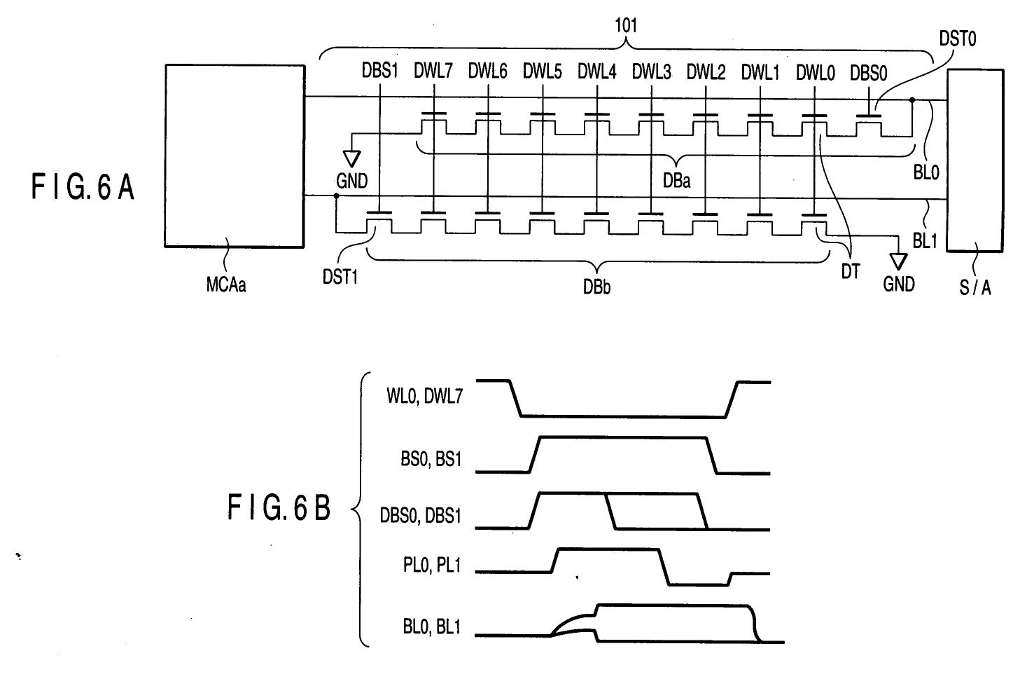

FIGS. 6A and 6B show a basic arrangement of a ferroelectric random access memory (FeRAM) (semiconductor memory device) of a series-connected TC unit type according to a third embodiment of the present invention. In the third embodiment, the FeRAM is so arranged that it can cancel (correct) an imbalance in bit line capacity which is caused by an imbalance in the capacity of a memory cell block MCB in read mode. FIG. 6A is a circuit diagram of the FeRAM, and FIG. 6B is a chart of signal waveforms of the data read operation.

The data read operation can be performed in the same manner as conventional. As has been described above, the memory cell blocks MCB-a and MCB-b connected to complementary (paired) bit lines BL0 and BL1 differ from each other in the position of unit cell UC (see FIG. 4A). In the memory cell block MCB-a connected to the bit line BL0, the unit cell UC connected to the word line WL1 is the second cell from the block select transistor ST. In the memory cell block MCB-b connected to the bit line BL1, the unit cell UC connected to the word line WL1 is the seventh cell from the block select transistor ST. In data read mode, therefore, an imbalance occurs between the capacity of the memory cell block MCB-a and that of the MCB-b, resulting in an imbalance in bit line capacity.

Referring to FIG. 6A, a correction circuit 101 can be provided between a memory cell array MCAa and a sense amplifier S/A to cancel an imbalance between the capacity of the memory cell block MCB-a and that of the memory cell block MCB-b in data read mode. More specifically, the correction circuit 101 includes a dummy block DBa that is made up of a given number (x=8) of dummy transistors DT connected in series. One end of the dummy block DBa is connected to a bit line BL0 via a dummy block select transistor DST0 whose gate terminal is connected to a dummy block select line DBS0. The other end of the dummy block DBa is connected to the ground (GND). The correction circuit 101 also includes a dummy block DBb that is made up of a given number (x=8) of dummy transistors DT connected in series. One end of the dummy block DBb is connected to a bit line BL1 via a dummy block select transistor DST1 whose gate terminal is connected to a dummy block select line DBS1. The other end of the dummy block DBb is connected to the ground (GND).

Dummy word lines DWL0 to DWL7 are connected to the gate terminals of the dummy transistors DT of the dummy block DBa in sequence from the dummy block select transistor DST0. On the other hand, dummy word lines DWL0 to DWL7 are connected to the gate terminals of the dummy transistors DT of the dummy block DBb in sequence from the GND.

In the correction circuit 101, the dummy word line DWL7 is selected at the same time when the word line WL0 is selected from the memory cell array MCAa as shown in FIG. 6B. The potentials of the word line WL0 and dummy word line DWL7 are pulled down from VPP to VSS and then the potentials of the block select lines BS0 and BS1 and those of the dummy block select lines DBS0 and DBS1 are pulled up from VSS to VPP. Thus, the parasitic capacities of complementary bit lines BL0 and BL1 can be made equal to each other in data read mode.

Similarly, the dummy word line DWL6 in the correction circuit 101 is selected at the same time when the word line WL1 is selected from the memory cell array MCAa. Thus, the parasitic capacities of complementary bit lines BL0 and BL1 can be made equal to each other in data read mode, with the result that an imbalance in read data can be prevented.

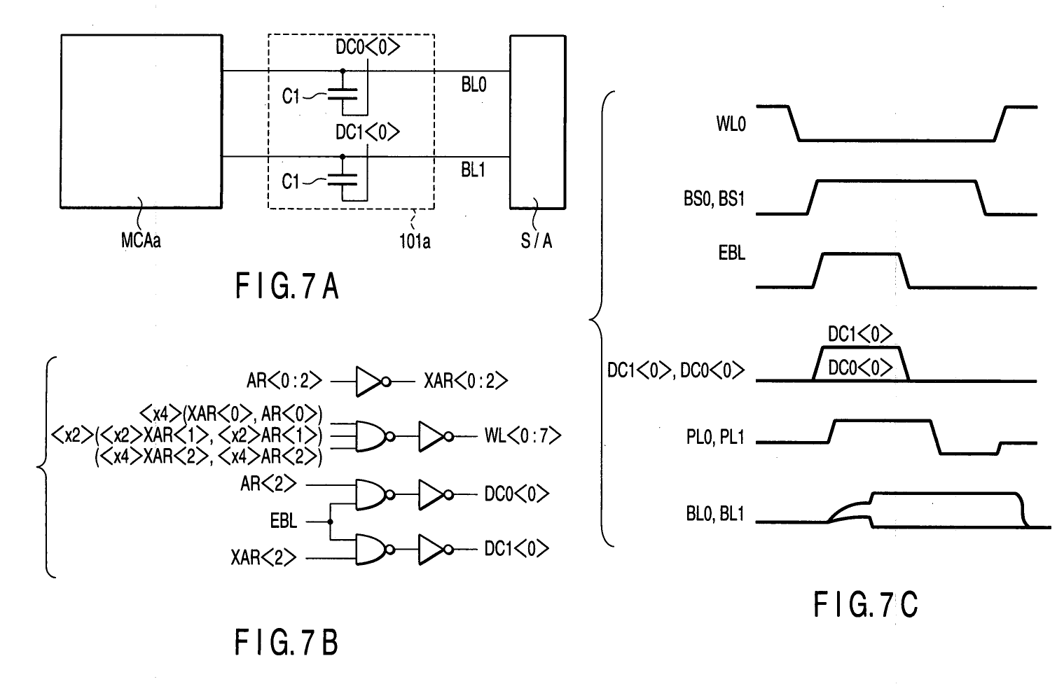

The second embodiment is not limited to the correction circuit 101. The correction circuit 101 can be replaced with a correction circuit 101a in which capacitors C1 and C1 (whose capacities are not equal to each other) are connected to complementary bit lines BL0 and BL1, respectively, as shown in FIGS. 7A to 7C. The correction circuit 101a can bring about the same advantage as the correction circuit 101. In other words, the correction circuit 101a can make the parasitic capacities of the bit lines BL0 and BL1 equal to each other in data read mode.

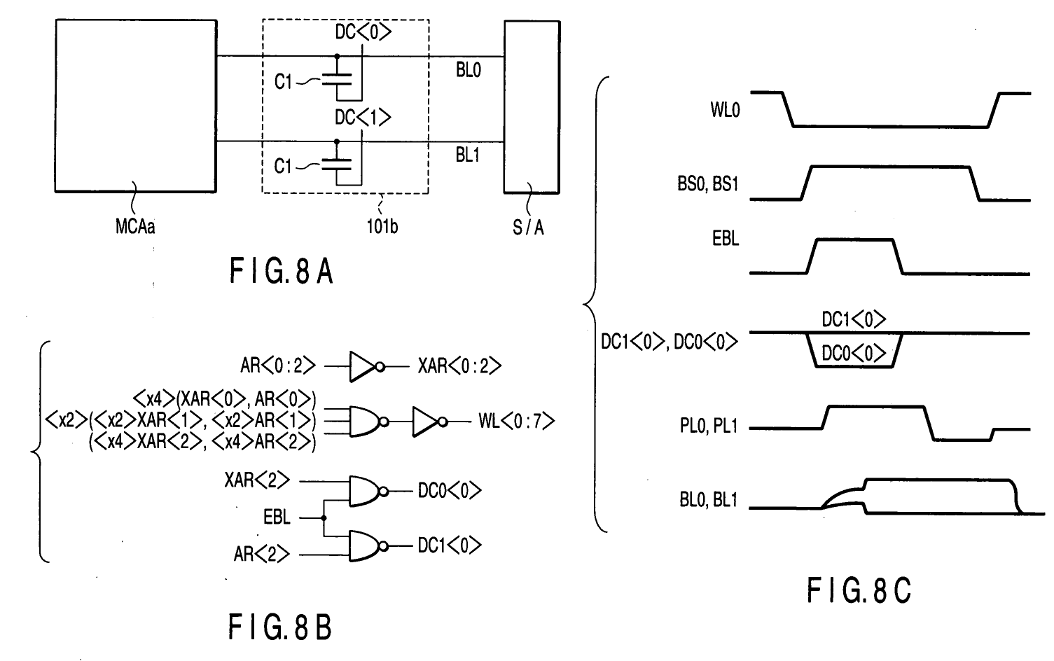

The correction circuit 101 can also be replaced with a correction circuit 101b in which capacitors C1 and C1 (whose capacities are equal to each other) are connected to complementary bit lines BL0 and BL1, respectively, as shown in FIGS. 8A to 8C. The correction circuit 101b can bring about the same advantage as the correction circuit 101. In other words, the correction circuit 101b can make the parasitic capacities of the bit lines BL0 and BL1 equal to each other in data read mode.

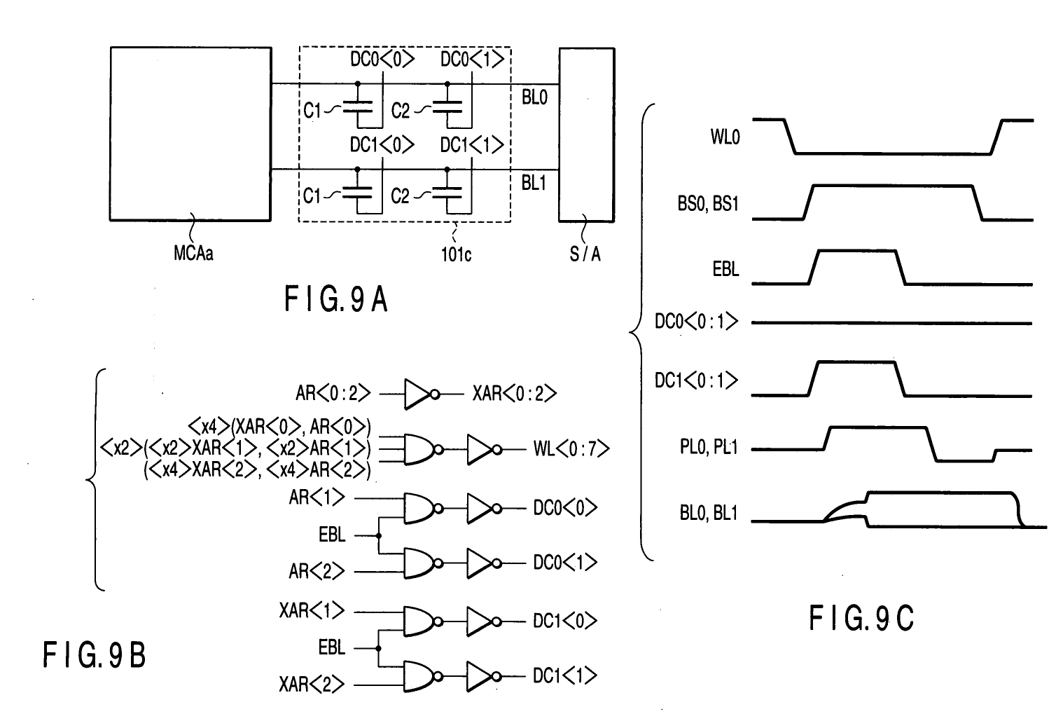

The correction circuit 101 can also be replaced with a correction circuit 101c in which capacitors C1 and C1 and capacitors C2 and C2 (the capacities of two capacitors C1 and C1 are equal to the capacity of one of the capacitors C2 and C2) are connected to complementary bit lines BL0 and BL1, respectively, as shown in FIGS. 9A to 9C. The correction circuit 101c can bring about the same advantage as the correction circuit 101. In other words, the correction circuit 101c can make the parasitic capacities of the bit lines BL0 and BL1 equal to each other in data read mode.

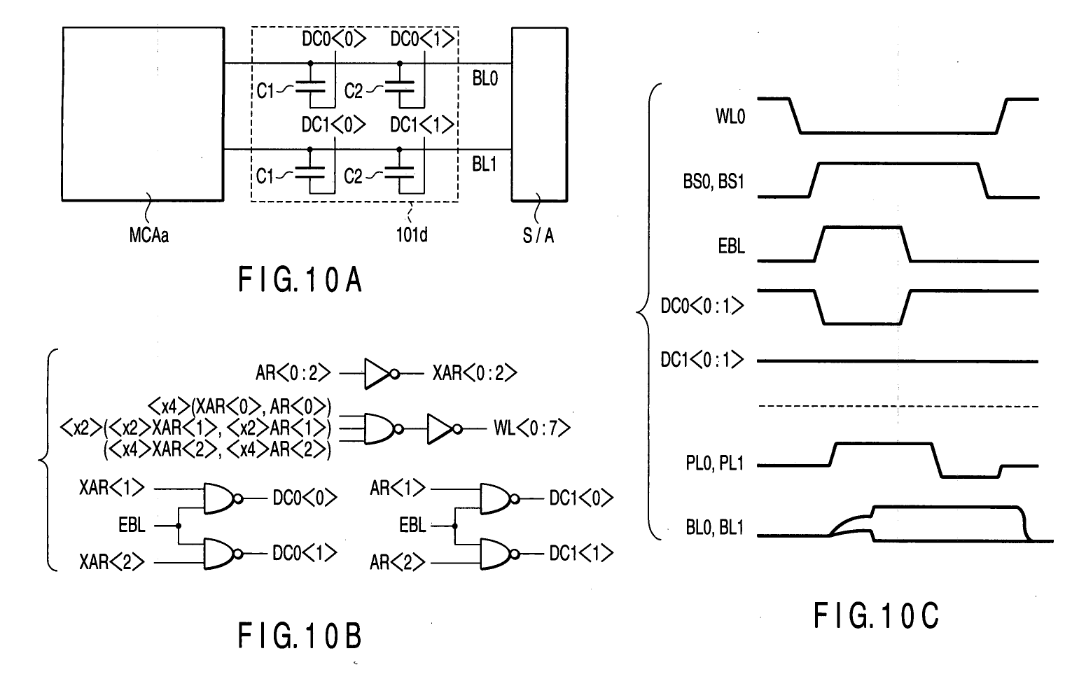

The correction circuit 101 can also be replaced with a correction circuit 101d in which capacitors C1 and C1 and capacitors C2 and C2 (the capacities of capacitors C1 and C1 are equal to each other, and the capacities of capacitors C2 and C2 are equal to each other) are connected to complementary bit lines BL0 and BL1, respectively, as shown in FIGS. 10A to 10C. The correction circuit 101d can bring about the same advantage as the correction circuit 101. In other words, the correction circuit 101d can make the parasitic capacities of the bit lines BL0 and BL1 equal to each other in data read mode.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a row of memory cells connected in series, each of the memory cells including a ferroelectric capacitor and a cell transistor which has a gate terminal and source/drain terminals, the source/drain terminals being connected in parallel with two electrodes of the ferroelectric capacitor;
a word line connected to the gate terminal;
memory cell blocks each including the row of memory cells and a block select transistor, a drain terminal of the block select transistor being connected to one end of the row of memory cells;
a plate line connected to another end of the row of memory cells;
a bit line connected to a source terminal of the block select transistor; and
a block select line connected to a gate terminal of the block select transistor,
wherein a contact is provided under the plate line to connect the source terminal of the block select transistor and the bit line.

2. The semiconductor memory device according to claim 1, wherein the memory cell blocks are arranged between a first block select line and a second block select line, which compose the block select line,
the first block select line is connected to a gate terminal of the block select transistor, which is connected to one of complementary pair of bit lines which compose the bit line, and
the second block select line is connected to a gate terminal of the block select transistor, which is connected to other of the complementary pair of bit lines.

3. The semiconductor memory device according to claim 1, wherein the plate line is arranged between a first block select line and a second block select line adjacent thereto, which compose the block select line,
the first block select line is connected to a gate terminal of a block select transistor of a first memory cell block, which is connected to the bit line, and
the second block select line is connected to a gate terminal of a block select transistor of a second memory cell block, which is connected to the bit line.

4. The semiconductor memory device according to claim 1, wherein the memory cell blocks each include x (x is a positive integer) memory cells, and a word line connected to a gate terminal of a y-th (y is a positive integer) memory cell from a block select transistor in a first memory cell block connected to one of complementary pair of bit lines which compose the bit line is connected to a gate terminal of an (x-y+1)-th memory cell from a block select transistor in a second memory cell block connected to other of the complementary pair of bit lines.

5. The semiconductor memory device according to claim 4, wherein a correction circuit is connected to the complementary pair of bit lines to correct an imbalance between capacities.

6. A semiconductor memory device comprising:
a row of memory cells connected in series, each of the memory cells including a ferroelectric capacitor and a cell transistor which has a gate terminal and source/drain terminals, the source/drain terminals being connected in parallel with two electrodes of the ferroelectric capacitor;
a word line connected to the gate terminal;
memory cell blocks each including the row of memory cells and a block select transistor, a drain terminal of the block select transistor being connected to one end of the row of memory cells;
a plate line connected to another end of the row of memory cells;
a complementary pair of bit lines each connected to a source terminal of the block select transistor;
a first block select line connected to a gate terminal of the block select transistor which is connected to one of the complementary pair of bit lines; and
a second block select line connected to a gate terminal of the block select transistor which is connected to other of the complementary pair of bit lines,
wherein the memory cell block are provided between the first block select line and the second block select line.

7. The semiconductor memory device according to claim 6, wherein a contact is provided under the plate line to connect the source terminal of the block select transistor and the bit line.

8. The semiconductor memory device according to claim 6, wherein the plate line is provided between a first block select line which is connected to a gate terminal of a block select transistor of a first memory cell block and a second block select line which is adjacent thereto and connected to a gate terminal of a block select transistor of a second memory cell block.

9. The semiconductor memory device according to claim 6, wherein the memory cell blocks each include x (x is a positive integer) memory cells, and a word line connected to a gate terminal of a y-th (y is a positive integer) memory cell from a block select transistor in a first memory cell block connected to one of the complementary pair of bit lines is connected to a gate terminal of an (x-y+1)-th memory cell from a block select transistor in a second memory cell block connected to other of the complementary pair of bit lines.

10. The semiconductor memory device according to claim 9, wherein a correction circuit is connected to the complementary pair of bit lines to correct an imbalance between capacities.

11. The semiconductor memory device according to claim 6, further comprising a third block select line connected to a gate terminal of the block select transistor which is connected to the one of the complementary pair of bit lines, a memory cell block connected to the third block select line being provided next to a memory cell block connected to the first block select line,
wherein the plate line is provided between the first block select line and the third block select line.

12. The semiconductor memory device according to claim 11, wherein a contact is provided under the plate line to connect the source terminal of the block select transistor and the bit line.

13. A semiconductor memory device comprising:
a row of memory cells connected in series, each of the memory cells including a ferroelectric capacitor and a cell transistor which has a gate terminal and source/drain terminals, the source/drain terminals being connected in parallel with two electrodes of the ferroelectric capacitor;
a word line connected to the gate terminal;
memory cell blocks each including the row of memory cells and a block select transistor, a drain terminal of the block select transistor being connected to one end of the row of memory cells;
a plate line connected to another end of the row of memory cells;
a bit line connected to a source terminal of the block select transistor; and
a block select line connected to a gate terminal of the block select transistor,
wherein the memory cell blocks each include x (x is a positive integer) memory cells, and a word line connected to a gate terminal of a y-th (y is a positive integer) memory cell from a block select transistor in a first memory cell block connected to one of complementary pair of bit lines which compose the bit line is connected to a gate terminal of an (x-y+1)-th memory cell from a block select transistor in a second memory cell block connected to other of the complementary pair of bit lines.

14. The semiconductor memory device according to claim 13, wherein a correction circuit is connected to the complementary pair of bit lines to correct an imbalance between capacities.

15. The semiconductor memory device according to claim 13, wherein a contact is provided under the plate line to connect the source terminal of the block select transistor and the bit line.

16. The semiconductor memory device according to claim 13, wherein the memory cell blocks are arranged between a first block select line and a second block select line, which compose the block select line,
the first block select line is connected to a gate terminal of the block select transistor, which is connected to one of complementary pair of bit lines which compose the bit line, and
the second block select line is connected to a gate terminal of the block select transistor, which is connected to other of the complementary pair of bit lines.

17. The semiconductor memory device according to claim 13, wherein the plate line is arranged between a first block select line and a second block select line adjacent thereto, which compose the block select line,
the first block select line is connected to a gate terminal of a block select transistor of a first memory cell block, which is connected to the bit line, and
the second block select line is connected to a gate terminal of a block select transistor of a second memory cell block, which is connected to the bit line.
